(19) United States
(12) Patent Application Publication
(10) Pub. No.: US 2022/0389162 A1
(43) Pub. Date: Dec. 8, 2022

(54) RESIN COMPOSITION AND RESIN-ATTACHED COPPER FOIL

(71) Applicant: MITSUI MINING & SMELTING CO., LTD., Tokyo (JP)

(72) Inventors: Kazuhiro OOSAWA, Ageo-shi (JP); Kuniharu OGAWA, Ageo-shi (JP); Haruka MAKINO, Ageo-shi (JP)

(73) Assignee: MITSUI MINING & SMELTING CO., LTD., Tokyo (JP)

(21) Appl. No.: 17/773,717

(22) PCT Filed: Oct. 27, 2020
(86) PCT No.: PCT/JP2020/040194

§ 371 Date: May 2, 2022

(30) Foreign Application Priority Data
Nov. 5, 2019 (JP) 2019-200483

(51) Int. Cl. C08G 65/48; C08F 236/06; C08F 212/08; C08K 5/01; C08K 5/5419; C08K 3/36; B32B 15/08; B32B 15/20

(52) U.S. Cl. CPC C08G 65/485; C08F 236/06; C08F 212/08; C08K 5/01; C08K 5/5419; C08K 3/36; B32B 15/08; B32B 15/20; C08K 2201/003; B32B 2311/12; B32B 2457/08; B32B 2307/204; B32B 2307/306

(57) ABSTRACT

There is provided a resin composition exhibiting excellent dielectric properties, high adhesion to a low-roughness surface, heat resistance, and excellent water resistance. This resin composition includes (a) a polymer having a polyphenylene ether backbone and a butadiene backbone in one molecule and having at least one selected from the group consisting of a vinyl group, a styryl group, an allyl group, an ethynyl group and a (meth)acryloyl group and at least any one of (b) a polymer including a styrene butadiene backbone and (c) a polymer including a cycloolefin backbone, wherein the content is the component (a) of 15 to 60 parts by weight and the total content of the component (b) and the component (c) is 40 to 85 parts by weight, based on 100 parts by weight of the total content of the component (a), the component (b), and the component (c).

### TECHNICAL FIELD

The present invention relates to a resin composition and a resin-attached copper foil.

### BACKGROUND ART

Printed wiring boards are widely used for electronic devices such as portable electronic devices. Particularly, frequencies of signals have been made higher with high functionalization of portable electronic devices and the like in recent years, and printed wiring boards suitable for such high-frequency applications have been demanded. These printed wiring boards for high frequencies are desired to have low transmission loss in order to enable transmission without deterioration in the quality of high-frequency signals. A printed wiring board includes: a copper foil processed into a wiring pattern; and an insulating resin substrate, and the transmission loss includes conductor loss mainly arising from the copper foil and dielectric loss arising from the insulating resin substrate. Accordingly, in a resin layer-attached copper foil which is applied to high-frequency applications, the dielectric loss arising from the resin layer is desirably suppressed. To achieve this, the resin layer is required to have excellent dielectric properties, particularly low dielectric loss tangent.

On the other hand, various resin compositions superior in dielectric properties and the like have been proposed for applications such as printed wiring boards. For example, Patent Literature 1 (JP2008-181909A) discloses a circuit substrate composition containing a thermosetting resin substrate, a glass fiber fabric, an inorganic particle filler, metallic coagents, and a bromine flame retardant. This thermosetting resin substrate comprises (a) a mixture of a high-molecular-weight polybutadiene thermosetting resin and a low-molecular-weight polybutadiene thermosetting resin and (b) a cycloolefin compound having two or more vinyl group double bonds, and/or a high-molecular-weight polymer of acrylic acid, acrylonitrile, and butadiene. Further, Patent Literature 2 (JP2005-502192A) relates to a method for forming a circuit member having a low dielectric constant and a low heat dissipation constant, and discloses disposing an adhesion-promoting elastomer layer between a copper foil and a circuit substrate material to stack the copper foil, the adhesion-promoting elastomer layer, and the circuit substrate material, thereby manufacturing the circuit member. In addition, a large number of elastomers and copolymers, such as an ethylene-propylene elastomer, an ethylene-propylene-diene monomer elastomer, a styrene-butadiene elastomer, and a styrene butadiene block copolymer and the copolymer, are enumerated as examples of the elastomer.

### CITATION LIST

### Patent Literature

Patent Literature 1: JP2008-181909A
Patent Literature 2: JP2005-502192A

### SUMMARY OF INVENTION

The present inventors have conducted studies on a resin composition which is superior in dielectric properties and the like and which can be pasted as a primer layer (adhesion layer) to a substrate such as a prepreg. The layer of this resin composition can be provided in the form of a resin-attached copper foil, and this copper foil can be used as a copper foil for forming a circuit. A resin composition for the above-described applications is desired to have not only excellent dielectric properties but also various properties such as being superior in adhesion even to a low-roughness surface (for example, a surface of a low-roughness copper foil), having heat resistance, and having excellent water resistance. In formation of a circuit for high frequencies among others, a low-roughness copper foil is desired from the viewpoint of reduction in transmission loss, but such a copper foil tends to have low adhesion to a resin composition because of low roughness. Therefore, how to achieve both excellent dielectric properties and high adhesion to a low-roughness copper foil while securing other properties is a problem.

The present inventors have discovered that by blending a particular polymer having a polyphenylene ether backbone and a butadiene backbone in one molecule with a polymer comprising a styrene butadiene backbone and/or a polymer comprising a cycloolefin backbone in a predetermined blending ratio, it is possible to provide a resin composition exhibiting excellent dielectric properties (for example, low dielectric loss tangent at 10 GHz), high adhesion to a low-roughness surface (for example, a surface of a low-roughness copper foil), heat resistance, and excellent water resistance (a low water absorption ratio).

Accordingly, an object of the present invention is to provide a resin composition exhibiting excellent dielectric properties, high adhesion to a low-roughness surface, heat resistance, and excellent water resistance.

According to an aspect of the present invention, there is provided a resin composition comprising the following components:
(a) a polymer having a polyphenylene ether backbone and a butadiene backbone in one molecule and having at least one selected from the group consisting of a vinyl group, a styryl group, an allyl group, an ethynyl group and a (meth)acryloyl group; and
at least any one of (b) a polymer comprising a styrene butadiene backbone and (c) a polymer comprising a cycloolefin backbone,
wherein the content of the component (a) is 15 parts by weight or more and 60 parts by weight or less and the total content of the component (b) and the component (c) is 40 parts by weight or more and 85 parts by weight or less, based on 100 parts by weight of a total content of the component (a), the component (b), and the component (c).

According to another aspect of the present invention, there is provided a resin-attached copper foil comprising:
a copper foil; and
a resin layer provided on at least one surface of the copper foil and comprising the resin composition.

### DESCRIPTION OF EMBODIMENTS

### Resin Composition

A resin composition of the present invention comprises (a) a polymer having a polyphenylene ether backbone and a butadiene backbone in one molecule and having at least one selected from the group consisting of a vinyl group, a styryl group, an allyl group, an ethynyl group, and a (meth)acryloyl group (hereinafter, referred to as component (a)). This resin composition further comprises at least any one of (b) a polymer comprising a styrene butadiene backbone (hereinafter, referred to as component (b)) and (c) a polymer comprising a cycloolefin backbone (hereinafter, referred to as component (c)). The content of the component (a) is 15 parts by weight or more and 60 parts by weight or less and the total content of the component (b) and the component (c) is 40 parts by weight or more and 85 parts by weight or less, based on 100 parts by weight of the total content of the component (a), the component (b), and the component (c). By blending a particular polymer having a polyphenylene ether backbone and a butadiene backbone in one molecule with a polymer comprising a styrene butadiene backbone and/or a polymer comprising a cycloolefin backbone in a predetermined blending ratio in this way, it is possible to provide a resin composition exhibiting excellent dielectric properties (for example, low dielectric loss tangent at 10 GHz), high adhesion to a low-roughness surface (for example, a surface of a low-roughness copper foil), heat resistance, and excellent water resistance (low water absorption ratio). In addition, this resin composition also has satisfactory processability, and, for example, this resin composition is unlikely to be broken and can exhibit satisfactory tackiness.

As described above, the present inventors have conducted studies on a resin composition which is superior in dielectric properties and the like and which can be pasted as a primer layer (adhesion layer) to a substrate such as a pregreg. The layer of this resin composition can be provided in the form of a resin-attached copper foil, and this copper foil can be used as a copper foil for forming a circuit. A resin composition for the above-described applications is desired to have not only excellent dielectric properties but also various properties such as being superior in adhesion even to a low-roughness surface (for example, a surface of a low-roughness copper foil), having heat resistance, and having excellent water resistance. In formation of a circuit for high frequencies among others, a low-roughness copper foil is desired from the viewpoint of reduction in transmission loss, but such a copper foil tends to have low adhesion to a resin composition because of low roughness. That is, when a material having a low-roughness surface (for example, a low-roughness copper foil) is bonded to an adherend such as a substrate using a primer layer (adhesion layer) of a resin composition (in the form of, for example, a resin-attached copper foil), peeling often occurs at an interface between the low-roughness surface and the resin composition layer, which is a smoother interface. It is considered that this is because the irregularity of the interface is extremely small (the thickness of the region where the interface is present is extremely thin) and therefore tensile stress concentrates two-dimensionally on the smooth interface where adhesion strength is the weakest.

When this tensile strength can be received more three-dimensionally at the layer of the resin composition (hereinafter referred to as resin layer) instead of the two-dimensional interface (that is, the stress can be dispersed to the inside of the resin layer), there is a possibility of preventing the peeling at the interface and improving the adhesion strength. As a method of improving the adhesion strength, reducing the elastic modulus of the resin layer where the stress is received, increasing the elongation percentage of the resin layer, thickening the resin layer, or forming a different phase of a filler or the like inside the resin layer is conceivable. However, with respect to the methods of giving flexibility to the resin layer, such as reducing the elastic modulus or increasing the elongation percentage, the peel strength (adhesion) of the resin-attached copper foil at normal temperature can be improved, but there is a tendency that the thermal properties such as heat resistance of the resin layer are likely to deteriorate depending on the resin having flexibility. In addition, when the resin layer is thickened, the thinness of the resin is sacrificed, and therefore the substrate at the time of stacking the substrate is thickened. Further, when a different phase of a filler or the like is formed inside the resin layer, control of the interfaces of the phase, such as securing the adhesion of the phase interfaces, optimizing the specific surface area of the phase interfaces, and securing the dispersibility of the phase in the production process, are needed, and a peel strength-improving effect cannot be obtained unless those complicated control of the interfaces of the phase is achieved. With regard to this point, according to the resin composition of the present invention, the above-described problems can be solved conveniently. It is considered that this is because continuous interfaces between polymers due to a polymer alloy (a micro-controlled, phase-separated structure) can be created in the resin composition by blending the polymer component (a) with the polymer component (b) and/or the polymer component (c) in a predetermined blending ratio. That is, it is considered that when tensile stress is applied in the form of a resin-attached copper foil or the like by a peel strength test or the like, the resin layer is first deformed before the peeling at the interface between the copper foil layer and the resin composition layer occurs, and the tensile stress is dispersed over the whole region in the thickness direction of the resin layer through the continuous interfaces between polymers, and thereby the tensile stress can be absorbed by the whole resin layer. That is, according to resin composition of the present invention, a resin layer capable of receiving the tensile stress three-dimensionally while having not only excellent dielectric properties but also heat resistance and water resistance can be formed, and therefore it is considered that high adhesion (high peel strength) to a low-roughness surface can be realized. Thus, according to the present invention, a resin composition exhibiting excellent dielectric properties, high adhesion to a low-roughness surface, heat resistance, and excellent water resistance is provided.

Specifically, the resin composition of the present invention preferably has a dielectric loss tangent at a frequency of 10 GHz after curing of less than 0.0030, more preferably less than 0.0020, and still more preferably less than 0.0015. The dielectric loss tangent is preferably lower, and the lower limit value is not particularly limited, but the dielectric loss tangent is typically 0.0001 or more. Further, the resin composition of the present invention preferably has a water absorption ratio after curing, measured in accordance with JIS C 6481-1996, of less than 0.5%, more preferably less than 0.3%, and still more preferably less than 0.1%. The water absorption ratio is preferably lower, and the lower limit value is not particularly limited, but the water absorption ratio is typically 0.01% or more.

The resin composition of the present invention comprises the component (a). The component (a) is a component that contributes mainly to thermosetting properties and heat resistance, and is a polymer having a polyphenylene ether backbone and a butadiene backbone in one molecule and having a predetermined reactive functional group. The predetermined reactive functional group is at least one selected from a vinyl group, a styryl group, an allyl group, an ethynyl group, and a (meth)acryloyl group, and the most suitable reactive functional group may be selected according to how much extent the reactivity is given, but a preferable reactive functional group is a vinyl group from the viewpoint of versatility. Further, the polyphenylene ether backbone and the butadiene backbone may take any polymerization morphology but are preferably polymerized through ester condensation from the viewpoint of heat resistance. The proportion of the polyphenylene ether backbone in the component (a) is not particularly limited, but the proportion is preferably higher from the viewpoint of heat resistance, and specifically, the proportion is 30% by weight or more and 80% by weight or less, and more preferably 50% by weight or more and 70% by weight or less. Forms which the vinyl group in the butadiene backbone can take in the component (a) are a 1,2-vinyl group and a 1,4-vinyl group. The amount of the 1,4-vinyl group is preferably as small as possible from the viewpoint of heat resistance and weatherability, and ultimately, hydrogen addition (hydrogenation treatment) may be performed on the 1,4-vinyl group. The molar ratio of the 1,4-vinyl group to the total amount of the 1,2-vinyl group and the 1,4-vinyl group is preferably 30% or less, more preferably 20% or less, and still more preferably 15% or less. Preferred examples of the component (a) include BX-660T manufactured by Nippon Kayaku Co., Ltd.

The content of the component (a) is 15 parts by weight or more and 60 parts by weight or less, preferably 20 parts by weight or more and 55 parts by weight or less, more preferably 20 parts by weight or more and 40 parts by weight or less, and still more preferably 25 parts by weight or more and 35 parts by weight or less, based on 100 parts by weight of the total content of the component (a), component (b), and the component (c). When the content of the component (a) is within these ranges, thereby the above-described properties can be realized more effectively.

The resin composition of the present invention further comprises at least any one of the component (b) and the component (c). The component (b) is a component that contributes mainly to peel strength and dielectric properties, and is a polymer comprising a styrene butadiene backbone (typically, a block copolymer of styrene and butadiene). This polymer may be any of a hydrogenated polymer or a non-hydrogenated polymer, but is preferably a hydrogenated polymer from the viewpoint of weatherability. With respect to the component (b), the styrene/ethylene-butylene ratio (S/EB ratio) is preferably within a range of 10/90 to 60/40, more preferably within a range of 20/80 to 40/60, and still more preferably within a range of 25/75 to 35/65 from the viewpoint of striking a balance among dielectric properties, flexibility, and peel strength. Preferred examples of the component (b) include Tuftec® MP-10 manufactured by Asahi Kasei Corp. On the other hand, the component (c) is a component that contributes mainly to dielectric properties, heat resistance, and peel after heating, and is a polymer comprising a cycloolefin backbone, and a polymer generally called a cycloolefin polymer (COP) can be used. Preferred examples of the component (c) include L-3PS manufactured by Zeon Corporation.

The total content of the component (b) and the component (c) is 40 parts by weight or more and 85 parts by weight or less, preferably 45 parts by weight or more and 80 parts by weight or less, more preferably 60 parts by weight or more and 80 parts by weight or less, and still more preferably 65 parts by weight or more and 75 parts by weight or less, based on 100 parts by weight of the total content of the component (a), component (b), and the component (c). When the total content of the component (b) and the component (c) is within these ranges, thereby the above-described properties can be realized more effectively.

The resin composition of the present invention preferably comprises both of the component (b) and the component (c). In this case, the weight ratio of the component (b) to the component (c), b/c, is preferably 0.8 or more and 10.0 or less, more preferably 1.0 or more and 8.0 or less, still more preferably 1.2 or more and 6.0 or less, and particularly preferably 1.2 or more and 4.5 or less. When the component (b) and the component (c) are used together, particularly when the weight ratio of those, b/c, is set within the above-described ranges, thereby the adhesion to a low-roughness surface (for example, a surface of a low-roughness copper foil) can further be enhanced. It is considered that this is because while the styrene butadiene backbone of the component (b) and the cycloolefin backbone of the component (c) are totally different from each other and are generally hard to mix, micro-controlled phase separation structures due to a polymer alloy can be created more effectively in the resin layer in the resin composition of the present invention. That is, it is considered that when tensile stress is applied in the form of a resin-attached copper foil or the like by a peel strength test or the like, the tensile stress can be dispersed at a higher degree over the whole region in the thickness direction of the resin layer through the fine and continuous interfaces between the component (b) and the component (c), and the tensile stress can be absorbed more effectively by the whole resin layer. Thus, a resin layer capable of receiving the tensile stress three-dimensionally can be realized more effectively.

The resin composition of the present invention preferably further comprises a silane coupling agent as a component (d). The silane coupling agent contributes to adhesion. Various silane coupling agents such as an amino-functional silane coupling agent, an acryl-functional silane coupling agent, a methacryl-functional silane coupling agent, an epoxy-functional silane coupling agent, an olefin-functional silane coupling agent, a mercapto-functional silane coupling agent, and a vinyl-functional silane coupling agent can be used as a silane coupling agent. Particularly, a silane coupling agent composed of a silane compound having three methoxy groups and/or ethoxy groups in total in a molecule is preferable, and specific examples of such a silane coupling agent include 8-methacryloxyoctyl trimethoxysilane, 8-glycidoxyoctyl trimethoxysilane, N-2-(aminoethyl)-8-aminooctyl trimethoxysilane, p-styryl trimethoxysilane, 7-octenyl trimethoxysilane, 3-glicidoxypropyl trimethoxysilane, 3-aminopropyl trimethoxysilane, 3-acryloxypropyl trimethoxysilane, and N-phenyl-3-aminopropyl trimethoxysilane. The content of the component (d), that is, the content of the silane coupling agent is preferably 0.10 parts by weight or more and 10.0 parts by weight or less, and is, from the viewpoint of suppressing an adverse influence on the dielectric properties and the like due to the addition of the coupling agent, more preferably 0.10 parts by weight or more and 5.0 parts by weight or less, still more preferably 0.10 parts by weight or more and 3.0 parts by weight or less, particularly preferably 0.10 parts by weight or more and 2.0 parts by weight or less, and most preferably 0.1 parts by weight or more and 1.5 parts by weight or less, based on 100 parts by weight of the total content of the component (a), the component (b), and the component (c).

The resin composition of the present invention may further comprise an inorganic filler as a component (e). Examples of the inorganic filler include silica, talc, and boron nitride (BN). The inorganic filler is not particularly limited as long as it can be dispersed in the resin composition, but is preferably silica from the viewpoint of dispersibility and dielectric properties. The average particle size D50 of the inorganic filler is preferably 0.1 to 3.0 μm, and more preferably 0.3 to 2.0 μm. When the inorganic filler has an average particle size D50 within such ranges, the number of interfaces (namely, the specific surface area) is decreased, and thereby an adverse influence on the dielectric properties can be reduced, and preferred properties as an electronic material, such as an improvement in interlayer insulation and disappearance of coarse particles in the resin layer, are brought about. The inorganic filler may take any form of a pulverized particle, a spherical particle, a core-shell particle, a hollow particle, and the like. The content of the component (e), that is, the content of the inorganic filler is preferably 50 parts by weight or more and 400 parts by weight or less, more preferably 50 parts by weight or more and 250 parts by weight or less, still more preferably 50 parts by weight or more and 200 parts by weight or less, and particularly preferably 50 parts by weight or more and 150 parts by weight or less, based on 100 parts by weight of the total content of the component (a), the component (b), and the component (c).

### Resin-Attached Copper Foil

The resin composition of the present invention is preferably used as a resin for a resin-attached copper foil. That is, according to a preferred aspect of the present invention, a resin-attached copper foil comprising a copper foil and a resin layer provided on at least one surface of the copper foil and comprising the resin composition is provided. Typically, the resin composition takes a form of a resin layer, and the resin composition is applied and dried on the copper foil using a gravure coating method in such a way that the thickness of the resin layer after drying takes a predetermined value, thereby obtaining the resin-attached copper foil. This coating method may be arbitrary, but the gravure coating method and other methods such as a die coating method and a knife coating method can be adopted. In addition, the resin composition can also be applied using a doctor blade, a bar coater, or the like.

As described above, the resin composition of the present invention exhibits excellent dielectric properties (for example, low dielectric loss tangent at 10 GHz), high adhesion to a low-roughness surface (for example, a surface of a low-roughness copper foil), heat resistance, and excellent water resistance (a low water absorption ratio). Accordingly, the resin-attached copper foil has various advantages brought about by such a resin composition. For example, the resin-attached copper foil preferably has a lower limit value of the peel strength (that is, peel strength in a normal state) between the resin layer and the copper foil, measured in accordance with JIS C 6481-1996 in a state where the resin layer is cured, of 0.6 kgf/cm or more, more preferably 0.7 kgf/cm or more, and particularly preferably 0.8 kgf/cm or more. The peel strength is better when it is higher, and the upper limit value thereof is not particularly limited, but is typically 2.0 kgf/cm or less.

Further, the resin-attached copper foil can exhibit high peel strength even after heating. Specifically, the resin-attached copper foil preferably has a lower limit value of the peel strength between the resin layer and the copper foil after the resin layer is cured and heated at 260° C. for 60 minutes (that is, a peel strength after heating), measured in accordance with JIS C 6481-1996, of 0.5 kgf/cm or more, more preferably 0.6 kgf/cm or more, still more preferably 0.7 kgf/cm or more, and particularly preferably 0.8 kgf/cm or more. The peel strength after heating is better when it is higher, and the upper limit value thereof is not particularly limited, but is typically 2.0 kgf/cm or less.

The thickness of the resin layer is not particularly limited, but appropriate thickness exists because the resin layer is preferably thicker and a multilayer substrate is preferably thinner in order to secure the peel strength. The thickness of the resin layer is preferably 1 μm or more and 50 μm or less, more preferably 2 μm or more and 20 μm or less, particularly preferably 3 μm or more and 10 μm or less, and most preferably 3 μm or more and 5 μm or less. When the thickness of the resin layer is within these ranges, thereby the above-described properties of the present invention can be realized more effectively, and the resin layer is easily formed by the application of the resin composition.

The copper foil may be a metal foil as produced by electrodepositing foil production or rolling foil production (that is, a raw foil) or may take a form of a surface-treated foil for which a surface treatment is performed on at least any one of the surfaces. The surface treatment can be any of various surface treatments which are performed on a surface of a metal foil in order to improve or impart a certain characteristic (for example, rust proofing performance, humidity resistance, chemical resistance, acid resistance, heat resistance, and adhesion to a substrate). The surface treatment may be performed on one surface of the metal foil or may be performed on both surfaces of the metal foil. Examples of the surface treatment which is performed on the copper foil include a rust proofing treatment, a silane treatment, a roughening treatment, and a barrier-forming treatment.

The surface of the resin layer side of the copper foil preferably has a ten-point average roughness Rzjis, as measured in accordance with JIS B0601-2001, of 0.5 μm or less, more preferably 0.4 μm or less, still more preferably 0.3 μm or less, and particularly preferably 0.2 μm or less. When the ten-point average roughness is within such ranges, the transmission loss in the high-frequency applications can desirably be reduced. That is, conductor loss which appears more remarkably when the frequency is higher, which can be increased by a skin effect of the copper foil, and which arises from the copper foil can be reduced, so that further reduction in the transmission loss can be realized. The lower limit value of the ten-point average roughness Rzjis of the surface on the resin layer side of the copper foil is not particularly limited, but from the viewpoint of an improvement in the adhesion to the resin layer and of the heat resistance, Rzjis is preferably 0.01 μm or more, more preferably 0.03 μm or more, and still more preferably 0.05 μm or more.

The thickness of the copper foil is not particularly limited but is preferably 0.1 μm or more and 100 μm or less, more preferably 0.5 μm or more and 70 μm or less, still more preferably 1 μm or more and 50 μm or less, particularly preferably 1.5 μm or more and 30 μm or less, and most preferably 2 μm or more and 20 μm or less. When the copper foil has a thickness within such ranges, there is an advantage that a fine circuit can be formed. However, in the case where the thickness of the copper foil is, for example, 10 μm or less, the resin-attached copper foil of the present invention may be a carrier-attached copper foil including a release layer and a carrier for the purpose of improving handleability, the carrier-attached copper foil having a resin layer formed on the surface of the copper foil thereof.

### EXAMPLES

The present invention will be described more specifically with reference to the following Examples.

### Examples 1 to 11

### (1) Preparation of Resin Varnish

Firstly, the components (a) to (e), described below, were provided as raw material components for resin varnishes.
Component (a): thermosetting polymer (BX-660T, manufactured by Nippon Kayaku Co., Ltd.) having a polyphenylene ether backbone and a butadiene backbone in one molecule and having a vinyl group as a reactive functional group
Component (b): hydrogenated styrene butadiene polymer (thermoplastic polymer) (Tuftec®, manufactured by Asahi Kasei Corp., product number: MP-10, styrene/ethylene-butadiene ratio (S/EB ratio)=30/70)
Component (c): cycloolefin polymer (thermoplastic polymer) (L-3PS, manufactured by Zeon Corporation)
Component (d): silane coupling agent (KBM-1403, manufactured by Shin-Etsu Chemical Co., Ltd., p-styryl trimethoxysilane)
Component (e): silica particle (ADMAFINE, manufactured by Admatechs Company Limited, product number: SC4050-MOT, average particle size D50: 1.0 μm)

The raw material components were weighed according to the blending ratio (weight ratio) shown in Table 1 and placed in a round flask, and a mixed solvent was added in such a way that the concentration of the raw material components was 28% by weight or 40% by weight. This mixed solvent was composed in such a way that the ratio of organic solvents in the resin varnishes was such that 85% by weight of toluene and 15% by weight of methyl ethyl ketone. To the round flask in which the raw material components and the mixed solvent were placed, a mantle heater and a flask cap with a stirring blade and a reflux condenser were installed, and after the temperature was increased to 60° C. under stirring, the stirring was continued at 60° C. for 2 hours to dissolve or disperse the raw material components. A resultant mixed solution was allowed to cool after the stirring. Thus, a resin varnish having a concentration of the raw material components of 28% by weight and a resin varnish having a concentration of the raw material components of 40% by weight were obtained.

### (2) Preparation of Electrodeposited Copper Foil

An electrodeposited copper foil (thickness 18 μm) was prepared by the following method. Electrolysis was performed using a rotating electrode (surface roughness Ra: 0.20 μm) made of titanium as a cathode and a dimension stable anode (DSA) as an anode in a copper sulfate solution at a solution temperature of 45° C. and a current density of 55 A/dm² to prepare an electrodeposited copper foil as a raw foil. The composition of this copper sulfate solution was set in such a way that the concentration of copper was 80 g/L, the concentration of free sulfuric acid was 140 g/L, the concentration of bis(3-sulfopropyl)disulfide was 30 mg/L, the concentration of a diallyl dimethyl ammonium chloride polymer was 50 mg/L, and the concentration of chlorine was 40 mg/L. Particulate protrusions were formed on the surface of the raw foil on the electrolytic solution surface side. The particulate protrusions were formed by performing electrolysis in a copper sulfate solution (concentration of copper: 13 g/L, concentration of free sulfuric acid 55 g/L, concentration of 9-phenyl acridine 140 mg/L, concentration of chlorine: 35 mg/L) under a condition of a solution temperature of 30° C. and a current density of 50 A/dm².

Zinc-nickel coat formation, chromate layer formation, and silane layer formation were performed in sequence under the conditions described below on the electrolytic solution surface side of the raw foil thus obtained.

### <Zinc-Nickel Coat Formation>

Concentration of potassium pyrophosphate: 80 g/L
Concentration of zinc: 0.2 g/L
Concentration of nickel: 2 g/L
Liquid temperature: 40° C.
Current density: 0.5 A/dm²

### <Chromate Layer Formation>

Concentration of chromic acid: 1 g/L, pH 11
Solution temperature: 25° C.
Current density: 1 A/dm²

### <Silane Layer Formation>

Silane coupling agent: 3-aminopropyl trimethoxysilane (3 g/L aqueous solution)
Liquid treatment method: shower treatment

The surface-treated surface of this electrodeposited copper foil had a ten-point average roughness Rzjis of 0.5 μm (in accordance with JIS B0601-2001), and the particulate protrusions had an average particle size of 100 nm as measured using a scanning electron microscopic image, and a particle density of 205 particles/μm².

### (3) Preparation of Resin Film

The obtained resin varnish having a concentration of the raw material components of 40% by weight was applied on the surface of the electrodeposited copper foil using a comma coater in such a way that the thickness of the resin after drying was 50 μm, and the applied resin varnish was dried in an oven at 150° C. for 3 minutes to obtain a resin-attached copper foil. Two resultant resin-attached copper foils were pasted together in such a way that the resins of the copper foils were in contact with each other, and vacuum pressing was performed under a condition of 190° C., 90 minutes, and 20 kgf/cm² to prepare a double-sided copper clad laminate was prepared. All the copper on both surfaces of the resultant double-sided copper clad laminate was etched away to obtain a resin film having a thickness of 100 μm.

### (4) Preparation of Thick Film

The obtained resin varnish having a concentration of the raw material components of 40% by weight was applied on the surface of a release film (“Aflex®” manufactured by AGC Inc.) using a comma coater in such a way that the thickness of the resin after drying was 50 μm, and the applied resin varnish was dried in an oven at 150° C. for 3 minutes to obtain a B-stage resin. The release film was released from the obtained B-stage resin, and 20 sheets of only the B-stage resins were stacked to apply vacuum pressing under a condition of 190° C., 90 minutes, and 20 kgf/cm², and thus a thick film having a thickness of 1000 μm was obtained.

### (5) Preparing Single-Sided Multilayer Substrate

The obtained resin varnish having a concentration of the raw material components of 28% by weight was applied on the surface of the electrodeposited copper foil using a gravure coater in such a way that the thickness of the resin after drying was 4 μm, and the applied resin varnish was dried in an oven at 150° C. for 2 minutes to obtain a resin-attached copper foil. A plurality of prepregs (“R-5680” manufactured by Panasonic Corporation) was stacked to make the thickness 0.2 mm, and the resin-attached copper foil was stacked thereon in such a way that the resin was in contact with the prepreg to apply vacuum pressing under a condition of 190° C., 90 minutes, and 30 kgf/cm², and thus a single-sided multilayer substrate was obtained.

### (6) Preparation of Double-Sided Multilayer Substrate

The obtained resin varnish having a concentration of the raw material components of 28% by weight was applied on the surface of the electrodeposited copper foil using a gravure coater in such a way that the thickness of the resin after drying was 4 μm, and the applied resin varnish was dried in an oven at 150° C. for 2 minutes to obtain a resin-attached copper foil. Prepregs (“R-5680” manufactured by Panasonic Corporation) were stacked to make the thickness 0.2 mm, the resin-attached copper foil was stacked on each of the top and bottom surfaces of the stacked prepregs in such a way that the resin was into contact with the prepreg to apply vacuum pressing under a condition of 190° C., 90 minutes, and 30 kgf/cm², and thus a double-sided multilayer substrate was obtained.

### (7) Evaluations

The following evaluations were performed for the prepared resin film, thick film, single-sided multilayer substrate, and double-sided multilayer substrate.

### <Evaluation 1: Peel Strength in Normal State>

Copper wiring having a wiring width of 10 mm and a wiring thickness of 18 μm was formed on the single-sided multilayer substrate by a subtractive method to measure the peel strength at normal temperature (for example, 25° C.) in accordance with JIS C 6481-1996. The measurement was performed 5 times, the average value was adopted as the value of the peel strength in a normal state, and the peel strength in a normal state was evaluated according to the following criteria. Note that the peel strength measured herein is a value in which four peeling modes, interfacial peeling between the prepreg/the resin, cohesive failure of the resin, phase interfacial peeling in the resin layer, and interfacial peeling between the resin/the copper foil, are reflected, and when the value is higher, it means that the copper wiring is more superior in adhesion to the prepreg substrate, strength of the resin layer, and adhesion of the resin to the low-roughness foil. The results were as shown in Table 1.
Rating A: 0.8 kgf/cm or more
Rating B: 0.7 kgf/cm or more and less than 0.8 kgf/cm
Rating C: 0.6 kgf/cm or more and less than 0.7 kgf/cm
Rating D: less than 0.6 kgf/cm
   <Evaluation 2: Peel Strength after Heating>

Copper wiring having a wiring width of 10 mm and a wiring thickness of 18 μm was formed on the single-sided multilayer substrate by a subtractive method, and after a heating treatment was performed in an oven at 260° C. for 60 minutes, the peel strength was measured in accordance with JIS C 6481-1996. Note that the measurement of the peel strength was performed not at 260° C. but after cooling from there to normal temperature (for example, 25° C.) (JIS C 6481-1996 stipulates that the measurement is performed at standard temperature of 15 to 35° C.). The measurement was performed 5 times, the average value was adopted as the value of the peel strength after heating, and the peel strength after heating was evaluated according to the following criteria. The results were as shown in Table 1.
Rating A: 0.7 kgf/cm or more
Rating B: 0.6 kgf/cm or more and less than 0.7 kgf/cm
Rating C: 0.5 kgf/cm or more and less than 0.6 kgf/cm
Rating D: less than 0.5 kgf/cm

### <Evaluation 3: Heat Resistance>

The double-sided multilayer substrate was cut out into a 0.7 cm square size to evaluate T-288 heat resistance using a thermomechanical analyzer (TMA) (TMA7100, manufactured by Hitachi High-Technologies Corporation) in accordance with IPC-TM-650. This evaluation was performed by increasing the temperature from normal temperature to 288° C. at 10° C./minute in a nitrogen atmosphere; keeping the temperature at 288° C. for 120 minutes while continuing to apply a compression load of 10 mN; and monitoring the displacement of the probe. That is, when gas generation due to pyrolysis or the like occurs, the double-sided multilayer substrate swells, and the swell is sensed as displacement. The maximum displacement during the 120 minutes, thus measured, was applied to the following criteria, and the heat resistance was thereby rated. The results were as shown in Table 1.
Rating A: the maximum displacement during the 120 minutes is less than 50 μm (no or small swell)
Rating D: the maximum displacement during the 120 minutes is 50 μm or more (large swell)

### <Evaluation 4: Dielectric Loss Tangent>

The dielectric loss tangent at 10 GHz was measured for the resin film alone by a perturbation cavity resonator method. After the resin film alone was cut to match the sample size of the resonator, this measurement was performed using a measurement apparatus (the resonator manufactured by KEYCOM Corp., and a network analyzer manufactured by KEYSIGHT Technologies) in accordance with JIS R 1641. The measured dielectric loss tangent was rated according to the following criteria. The results were as shown in Table 1.
Rating A: the dielectric loss tangent at 10 GHz is less than 0.0015
Rating B: the dielectric loss tangent at 10 GHz is 0.0015 or more and less than 0.0020
Rating C: the dielectric loss tangent at 10 GHz is 0.0020 or more and less than 0.0030
Rating D: the dielectric loss tangent at 10 GHz is 0.0030 or more

### <Evaluation 5: Water Absorption Ratio>

Five test pieces having a size of 50 mm×50 mm were cut out from the thick film. The water absorption ratio was measured for these test pieces in accordance with JIS C 6481-1996, the average value was adopted as a representative value of the water absorption ratio, and the water absorption ratio was evaluated according to the following criteria. The results were as shown in Table 1.
Rating A: the value of the water absorption ratio is less than 0.1%
Rating B: the value of the water absorption ratio is 0.1% or more and less than 0.3%
Rating C: the value of the water absorption ratio is 0.3% or more and less than 0.5%
Rating D: the value of the water absorption ratio is 0.5% or more

TABLE 1

| | | | Example | Example | Example | Example | Example | Example |
|---|---|---|---|---|---|---|---|---|
| | | | 1 | 2 | 3 | 4 | 5 | 6 |
| Blending ratio of components of resin | (a) | BX-660T | 20.00 | 35.00 | 55.00 | 35.00 | 35.00 | 35.00 |
| composition (parts by weight) | (b) | MP-10 | 48.02 | 39.02 | 27.01 | 0.00 | 26.00 | 29.25 |
| | (c) | L-3PS | 31.98 | 25.98 | 17.99 | 65.00 | 39.00 | 35.75 |
| | (d) | KBM-1403 | 0.20 | 0.20 | 0.20 | 0.20 | 0.20 | 0.20 |
| | (e) | SC4050-MOT | 100.00 | 100.00 | 100.00 | 100.00 | 100.00 | 100.00 |

| | | | | | | | |
|---|---|---|---|---|---|---|---|
| | Total | 200.20 | 200.20 | 200.20 | 200.20 | 200.20 | 200.20 |
| Evaluation results | Peel strength in normal | A | B | B | C | C | B |
| | state (kgf/cm) | 0.84 | 0.78 | 0.70 | 0.63 | 0.67 | 0.72 |
| | Peel strength after | A | B | c | A | B | B |
| | heating (kgf/cm) | 0.75 | 0.69 | 0.55 | 0.79 | 0.65 | 0.67 |
| | Heat resistance | A | A | A | A | A | A |
| | Dielectric loss tangent | A | B | C | A | B | B |
| | | 0.0014 | 0.0016 | 0.0021 | 0.0014 | 0.0016 | 0.0016 |
| | Water absorption ratio | A | A | A | A | A | A |
| | (%) | 0.05 | 0.05 | 0.08 | 0.04 | 0.04 | 0.05 |

| | | | Example | Example | Example | Example | Example |
|---|---|---|---|---|---|---|---|
| | | | 7 | 8 | 9 | 10* | 11* |
| Blending ratio of | (a) | BX-660T | 35.00 | 35.00 | 35.00 | 10.00 | 70.00 |
| components of resin | (b) | MP-10 | 49.40 | 52.65 | 65.00 | 54.02 | 18.01 |
| composition | (c) | L-3PS | 15.60 | 12.35 | 0.00 | 35.98 | 11.99 |
| (parts by weight) | (d) | KBM-1403 | 0.20 | 0.20 | 0.20 | 0.20 | 0.20 |
| | (e) | SC4050-MOT | 100.00 | 100.00 | 100.00 | 100.00 | 100.00 |

| | | | | | | |
|---|---|---|---|---|---|---|
| | Total | 200.20 | 200.20 | 200.20 | 200.20 | 200.20 |
| Evaluation results | Peel strength in normal | A | A | B | A | C |
| | state (kgf/cm) | 0.89 | 0.93 | 0.77 | 0.83 | 0.62 |
| | Peel strength after | A | A | A | A | D |
| | heating (kgf/cm) | 0.76 | 0.77 | 0.78 | 0.87 | 0.45 |
| | Heat resistance | A | A | A | D | D |
| | Dielectric loss tangent | B | B | B | A | C |
| | | 0.0016 | 0.0017 | 0.0017 | 0.0010 | 0.0024 |
| | Water absorption ratio | A | A | A | A | B |
| | (%) | 0.07 | 0.04 | 0.07 | 0.03 | 0.13 |

*denotes Comparative Example

1. A resin composition comprising the following components:
(a) a polymer having a polyphenylene ether backbone and a butadiene backbone in one molecule and having at least one selected from the group consisting of a vinyl group; a styryl group, an allyl group, an ethynyl group and a (meth)acryloyl group; and
at least any one of (b) a polymer comprising a styrene butadiene backbone and (c) a polymer comprising a cycloolefin backbone,
wherein the content of the component (a) is 15 parts by weight or more and 60 parts by weight or less and the total content of the component (b) and the component (c) is 40 parts by weight or more and 85 parts by weight or less; based on 100 parts by weight of a total content of the component (a), the component (b), and the component (c).

2. The resin composition according to claim 1, wherein the content of the component (a) is 20 parts by weight or more and 55 parts by weight or less.

3. The resin composition according to claim 1, comprising both of the component (b) and the component (c).

4. The resin composition according to claim 3, wherein a weight ratio of the component (h) to the component (c), b/c, is 0.8 or more and 10.0 or less.

5. The resin composition according to claim 1, wherein the resin composition further comprises (d) a silane coupling agent, and
wherein the content of the component (d) is 0.10 parts by weight or more and 10.0 parts by weight or less, based on 100 parts by weight of the total content of the component (a), the component (b), and the component (c).

6. The resin composition according to claim 1, wherein the resin composition further comprises (e) an inorganic filler, and
wherein the content of the component (e) of 50 parts by weight or more and 400 parts by weight or less, based on 100 parts by weight of the total content of the component (a), the component (b), and the component (c).

7. The resin composition according to claim 1, having a dielectric loss tangent at a frequency of 10 GHz after curing of less than 0.0030.

8. The resin composition according to claim 1, having a water absorption ratio after curing, as measured in accordance with JIS C 6481-1996, of less than 0.5%.

9. A resin-attached copper foil comprising:
a copper foil; and
a resin layer provided on at least one surface of the copper foil and comprising the resin composition according to claim 1.

10. The resin-attached copper foil according to claim 9, wherein a surface of the resin layer side of the copper foil has a ten-point average roughness Rzjis of 0.5 μm or less as measured in accordance with JIS B0601-2001.

11. The resin-attached copper foil according to claim 9, wherein a peel strength in a normal state between the resin layer and the copper foil, as measured in accordance with JIS C 6481-1996 in a state where the resin layer is cured, is 0.6 kgf/cm or more.

12. The resin-attached copper foil according to claim 9, wherein a peel strength between the resin layer and the copper foil after the resin layer is cured and heated at 260° C. for 60 minutes, as measured in accordance with JIS C 6481-1996, is 0.5 kgf/cm or more.
